(19) United States
(12) Patent Application Publication
(10) Pub. No.: US 2022/0068986 A1
(43) Pub. Date: Mar. 3, 2022

(54) METHOD FOR MANUFACTURING IMAGING MODULE

(71) Applicant: Ningbo Semiconductor International Corporation, Ningbo, Zhejiang (CN)

(72) Inventor: Luo GUI, Ningbo, Zhejiang (CN)

(73) Assignee: Ningbo Semiconductor International Corporation, Ningbo, Zhejiang (CN)

(21) Appl. No.: 17/415,012

(22) PCT Filed: Jul. 1, 2020
(86) PCT No.: PCT/CN2020/099642

§ 371 Date: Jun. 17, 2021

(30) Foreign Application Priority Data
Nov. 21, 2019 (CN) 201911149419.2

(51) Int. Cl. H01L 27/146; H01L 41/293; H01L 41/312

(52) U.S. Cl. CPC H01L 27/1469; H01L 41/312; H01L 41/293

(57) ABSTRACT

A method for manufacturing an imaging module, including: providing a first substrate and bonding a first dielectric layer on the first substrate; patterning the first dielectric layer to form at least one first bump and at least one second bump which are mutually independent, wherein a region surrounded by the at least one second bump defines a location region of the moved element; providing a piezoelectric element, adhering one end of the piezoelectric element to the first bump through a first adhesion material and making the other end of the piezoelectric element at least partially located above the second bump; adhering the moved element to the second bump through a second adhesion material; and debonding to remove the first substrate.

### FIELD OF TECHNOLOGY

The present disclosure relates to the field of manufacturing of semiconductor devices, in particular to a method for manufacturing an imaging module.

### BACKGROUND

In some electronic terminals, it is usually necessary to translate, vertically move or incline some parts of the electronic terminals so as to realize some special functions. For example, at present, in various electronic terminals such as video cameras, cameras and mobile phones with lens modules, a movable lens or image sensor may generate displacement in an optic axis direction for focusing or zooming, or generate displacement in a direction vertical to the optic axis direction to prevent optical jittering usually through driving mechanisms such as a voice coil actuator/voice coil motor (VCM), etc. However, different form the traditional single lens reflex camera, it is a great engineering challenge to realize the function in the electronic terminals with narrow space, such as mobile phone, mini video cameras, cameras, etc. Furthermore, as the imaging systems of the electronic terminals such as the mobile phones become more and more complex and the lens modules become heavier and heavier, the traditional driving mechanism such as the VCM has gradually insufficient driving ability and a complex structure, and occupies a large space.

Therefore, a method for manufacturing an imaging module is expected, such that the occupied space can be reduced and sufficient driving ability can be provided for the moved element, thereby meeting the movement requirements of the moved element.

### SUMMARY

An objective of the present disclosure is to provide a method for manufacturing an imaging module, which uses a bonding process to form a groove for accommodating an end part of a piezoelectric element on a bottom surface of a moved element and uses the warpage of the piezoelectric element to move the moved element.

To achieve the above objective, the present disclosure provides a method for manufacturing an imaging module. The imaging module includes:
a moved element, wherein the moved element includes: an imaging sensing element, an aperture, a lens or a reflector. The method includes:
providing a first substrate and bonding a first dielectric layer on the first substrate;
patterning the first dielectric layer to form at least one first bump and at least one second bump, wherein the at least one first bump and the at least one second bump are mutually independent, and a region surrounded by the at least one second bump defines a location region of the moved element;
providing a piezoelectric element, adhering one end of the piezoelectric element to the first bump through a first adhesion material and making the other end of the piezoelectric element at least partially located above the second bump, wherein under the power-on state, the other end of the piezoelectric element is warped upwards or downwards so as to drive the moved element to move upwards or downwards;
adhering the moved element to the second bump through a second adhesion material, wherein the moved element and the second bump have opposite parts, a groove is surrounded by the moved element, the second adhesion material and the second bump, or the moved element is provided with a film layer extending out of the moved element and a groove is surrounded by the film layer, the second adhesion material and the second bump; and
debonding to remove the first substrate.

In conclusion, a groove in an embodiment of the present disclosure is configured to provide a space for a movable end of the piezoelectric element to slide so as to drive the moved element to move up and down. The groove is formed by bonding instead of using a sacrificial layer material, such that the application range is enlarged. The groove is also suitable when the moved element is an intolerant sacrificial layer release process.

A bottom surface of the moved element may directly serve as a top surface of the groove, and a bottom surface of the groove and a first bump for supporting the piezoelectric element are formed in one process, so the process flow is saved. An adhesion material for adhering the moved element to the bottom surface of the groove together directly serves as a side wall of the groove. When the moved element has a small size, or the bottom surface of the moved element is not suitable for serving as a top surface of the groove due to other reasons, a film layer extending outwards may be formed on the bottom surface of the moved element, and the film layer serves as the top surface of the groove. In addition, a third bump is manufactured and adheres to a bottom surface of the first bump, so that the moved element may move up and down. The positions of the formed first bump and second bump are flexible, and the piezoelectric element may realize various distribution modes.

### BRIEF DESCRIPTION OF THE DRAWINGS

FIG. 1 is a flowchart of steps of a method for manufacturing an imaging module according to an example of the present disclosure.

FIG. 2 to FIG. 16 are structural schematic diagrams corresponding to different steps in the manufacturing process of a method for manufacturing an imaging module according to an embodiment of the present disclosure.

FIG. 17 to FIG. 21 are structural schematic diagrams corresponding to different steps in the manufacturing process of a method for manufacturing an imaging module according to another embodiment of the present disclosure.

FIG. 22 is a partial schematic diagram of an imaging module according to an embodiment of the present disclosure.

FIG. 23 is a schematic diagram of a piezoelectric element structure of a multi-layer piezoelectric film according to an embodiment of the present disclosure.

FIG. 24 is a schematic diagram of the formation of an interconnection structure in a first bump according to an embodiment of the present disclosure.

FIG. 25 is a schematic diagram of the formation of an interconnection structure in a first bump according to an embodiment of the present disclosure.

### DESCRIPTION OF REFERENCE NUMERALS

01-First substrate; 02-bonding film; 03-first dielectric layer; 04-first bump; 041-first electrical connection end; 042-second electrical connection end; 043-conductive plug; 05-second bump; 06-first adhesion material; 07-piezoelectric element; 08-second adhesion material; 09-moved element; 10-film layer; 11-second substrate; 12-bonding film; 13-second dielectric layer; 14-third bump; 16-third adhesion material; 072-supporting layer; 073-second electrode; 074-piezoelectric film; 075-first electrode; 076-insulating layer; 0761-first electrode leading-out end; 0762-second electrode leading-out end; 077-conductive structure; 0711-odd-layer electrode; 0721-even-layer electrode; 20-circuit board; 30-lead.

### DESCRIPTION OF THE EMBODIMENTS

A method for manufacturing an element bulk acoustic resonator of the present disclosure is further described below in detail with reference to the accompanying drawings and the specific embodiments. According to the following description and the accompanying drawings, the advantages and features of the present disclosure will be clearer. However, it should be noted that the concept of the technical solution of the present disclosure may be implemented according to various different forms, and is not limited to the specific embodiments described herein. The accompanying drawings all adopt very simplified forms and use inaccurate scale, which are only used for conveniently and clearly assisting in describing the objective of the embodiment of the present disclosure.

It should be understood that when an element or layer is referred to as “on”, “adjacent to”, “connected to” or “coupled to” other elements or layers, the element or layer may be directly on, adjacent to, connected to or coupled to other elements or layers, or there may be an element or layer between the element or layer and other elements or layers. On the contrary, when an element is referred to as “directly on”, “directly adjacent to”, “directly connected to” or “directly coupled to” other elements or layers, there is no element or layer between the element or layer and other elements or layers. It should be understood that although terms first, second, third, etc. may be used to describe various elements, parts, regions, layers and/or portions, these elements, parts, regions, layers and/or portions should not be limited by these terms. These terms are only used to distinguish one element, part, region, layer or portion from another element, part, region, layer or portion. Therefore, without departing from the instruction of the present disclosure, a first element, part, region, layer or portion discussed below may be represented as a second element, part, region, layer or portion.

Spatial relationship terms such as “under”, “below”, “over”, “above”, etc. may be used herein for the convenience of description so as to describe a relationship between one element ore feature shown in the drawings and other elements or features. It should be understood that in addition to an orientation shown in the drawings, the spatial relationship terms are intended to further include different orientations of devices during use and operation. For example, if devices in the drawings are turned over, an element or feature which is described to be “below” or “under” other elements or features will be oriented to be “above” other elements or features. Therefore, exemplary terms “under” and “below” may include upper and lower orientations. Devices may be otherwise oriented (rotating by 90 degrees or adopting other orientations), and spatial description words used therein are accordingly explained.

The terms used herein are only intended to describe the specific embodiments and not to limit the present disclosure. When used herein, the singular forms “a”, “an” and “the” are also intended to include the plural forms, unless the context clearly indicates otherwise. It should also be understood that terms “comprise” and/or “include”, when used in the specification, are used to determine the presence of the feature, integer, step, operation, element and/or part, but do not exclude the presence or addition of more other features, integers, steps, operations, elements, parts and/or groups. When used herein, the term “and/or” includes any and all combinations of related listed items.

If the method of the present disclosure includes a series of steps, the order of these steps presented herein is not necessarily the only order in which these steps may be performed, and some steps may be omitted and/or some other steps not described herein may be added to the method. If elements in a certain drawing are as same as elements in other drawings, these elements may be easily identified, but in order to make the description of the drawings clearer, the description will not mark the reference numerals of all the same elements in each drawing.

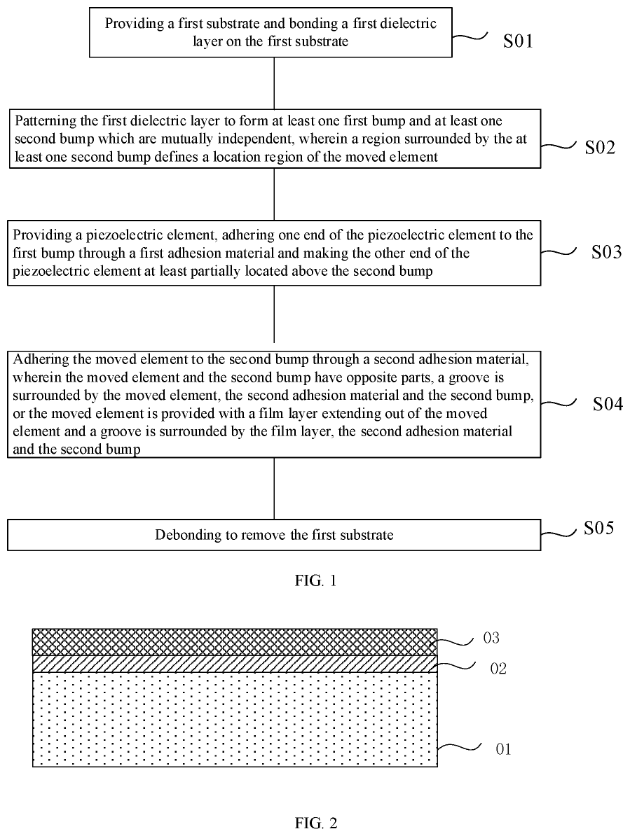

An embodiment of the present disclosure provides a method for manufacturing an imaging module. Referring FIG. 1 which is a flowchart of a method for manufacturing an imaging module according to an embodiment of the present disclosure, the imaging module includes a moved element, wherein the moved element includes: an imaging sensing element, an aperture, a lens or a reflector. The method includes:
S01: a first substrate is provided and a first dielectric layer is bonded on the first substrate; S02: the first dielectric layer is patterned to form at least one first bump and at least one second bump which are mutually independent, wherein a region surrounded by the at least one second bump defines a location region of the moved element; S03: a piezoelectric element is provided, one end of the piezoelectric element adheres to the first bump through a first adhesion material and the other end of the piezoelectric element at least partially is located above the second bump, wherein under the power-on state, the other end of the piezoelectric element is warped upwards or downwards so as to drive the moved element to move upwards or downwards; S04: the moved element adheres to the second bump through a second adhesion material, wherein the moved element and the second bump have opposite parts, a groove is surrounded by the moved element, the second adhesion material and the second bump, or the moved element is provided with a film layer extending out of the moved element, and a groove is surrounded by the film layer, the second adhesion material and the second bump; and debonding is performed to remove the first substrate.

The method for forming the imaging module is described below with referent to FIG. 2 to FIG. 16. FIG. 2 to FIG. 16 are structural schematic diagrams corresponding to each step in an embodiment of a method for manufacturing an imaging module according to the present disclosure.

Referring to FIG. 2, a first substrate 01 is provided, and a first dielectric layer 03 is bonded on the first substrate 01 through a bonding film 02. The first substrate 01 is configured to temporarily bear an imaging module structure. After the imaging module is formed, it is necessary to remove the first substrate 01. A material of the first substrate 01 may be any one of the following mentioned materials: silicon (Si), germanium (Ge), silicon-germanium (SiGe), silicon carbide (SiC), carbon silicon-germanium (SiGeC), indium arsenide (InAs), gallium arsenide (GaAs), indium phosphide (InP) or other III/V compound semiconductor or glass. In this embodiment, a material of the first substrate 01 is monocrystalline silicon. The bonding film 02 is configured to bond the first dielectric layer 03 on the first substrate 01. The bonding film 02 may be a pyrolysis film or an ultraviolet photolysis film. In this embodiment, the bonding film 02 is the pyrolysis film. When bonding is performed by the pyrolysis film, the material of the first substrate 01 may be selected in a wide range, including opaque or translucent. The first dielectric layer 03 is subsequently configured to form a first bump 04 and a second bump 05. In the later process, the first bump 04 is configured to fixing a fixed end of a piezoelectric element, and a movable end of the piezoelectric element is located above the second bump. A material of the first dielectric layer 03 refers to the material of the first substrate 01. In this embodiment, the material of the first dielectric layer 03 is monocrystalline silicon. A method for forming the first dielectric layer 03 includes: forming the first dielectric layer 03 on the bonding film 02 through physical vapor deposition or chemical vapor deposition.

In another embodiment, the bonding film 02 is an ultraviolet photolysis film. The ultraviolet photolysis film will lose viscosity after being irradiated by ultraviolet light, and debonding is performed subsequently through ultraviolet irradiation. The premise of using the ultraviolet photolysis film is that the material of the first substrate 01 is a translucent material such as glass, and ultraviolet light may irradiate on the ultraviolet photolysis film through a glass substrate. When the bonding film 02 is the ultraviolet photolysis film and the first substrate 01 is glass, the glass is non-conductive and charges generated by an etching process cannot be released in the later etching process, so it is necessary to adhere one layer of electrostatic film with a conductive function (not shown in the figure) to release the charges, and the electrostatic film adheres to a lower surface, opposite to the first dielectric layer 03, of the first substrate 01. In addition, when the etching or other processes requiring position alignment are performed, the translucency of the glass is unfavorable for position alignment, so the electrostatic film is required not to be translucent, at least not to be completely translucent.

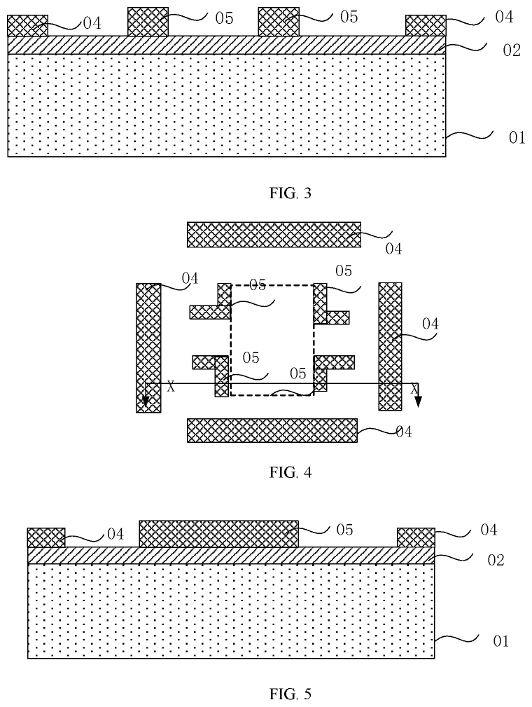

Referring to FIG. 3 and FIG. 4, FIG. 4 is a top view, and FIG. 3 is a sectional view along an X-X direction in FIG. 4. The first dielectric layer 03 is patterned to form at least one first bump 04 and at least one second bump 05, wherein the at least one first bump 04 and the at least one second bump 05 are mutually independent, and a region surrounded by the at least one second bump 05 is defined as a location region of the moved element, such as a region shown in a dashed box in FIG. 4. The moved element includes: an imaging sensing element, an aperture, a lens or a reflector. That the region surrounded by the second bump 05 defines the location region of the moved element should be understood as follows: the moved element is arranged at a space above the region surrounded by the second bump 05, the moved element may completely cover the second bump 05, or part of an edge of the second bump 05 is located at the periphery of the moved element, the first bump 04 may be located at a space below the moved element or may also be located at the periphery of the moved element, a region surrounded by the first bump 04 may surround the region surrounded by the second bump 05, and the region surrounded by the second bump 05 may also surround the region surrounded by the first bump 04.

Before the first dielectric layer 03 is patterned, the method further includes: the first dielectric layer 03 is thinned. A method for patterning the first dielectric layer 03 includes: the first dielectric layer 03 is spin-coated with a photoresist layer, the photoresist layer is exposed and developed to form a patterned photoresist layer, the patterned photoresist layer serves as a mask, and the patterned photoresist layer exposes part of a surface of the first dielectric layer 03; and the first dielectric layer 03 is etched by taking the patterned photoresist layer as the mask to form a first bump 04 and a second bump 05, wherein the first bump 04 and the second bump 05 are mutually independent.

A height of the first bump 04 is less than a height of the second bump 05. Specifically, a method for making the height of the first bump 04 less than the height of the second bump 05 includes: the first dielectric layer 03 is coated with photoresist, and masks with different light transmittance are adopted, for example, the mask is divided into a fully-transparent region, a semi-transparent region and an opaque region, wherein the fully-transparent region corresponds to a region where the first dielectric layer 03 needs to be completely etched, the semi-transparent region corresponds to a region where the first bump 04 is formed, and the opaque region corresponds to a region where the second bump 05 is formed. When the exposure and development process is performed, the photoresist in the fully-transparent region is completely removed, the remaining photoresist with partial thickness in the semi-transparent region is not removed, and the photoresist in the opaque region has the complete thickness during coating. When the etching process is performed, in the region covered with the photoresist with partial thickness, the photoresist is firstly etched and then the first dielectric layer 03 is etched, and therefore, within the same time, the first dielectric layer 03 in the region not covered with the photoresist is all etched, the dielectric layer 03 in the region covered with the photoresist with complete thickness is not etched, the first dielectric layer 03 in the region covered with the photoresist with partial thickness is etched with partial thickness, and the height of the formed first bump 04 is less than that of the second bump 05.

Subsequently, the piezoelectric element adheres to the first bump 04 generally by a dry film or a structural adhesive. No matter which adhesion methods, the adhesion materials have a certain thickness. If the first bump 04 and the second bump 05 have the consistent thickness during formation, the unfixed end of the piezoelectric element will be in a suspended state. Therefore, when the height of the formed first bump 04 is less than that of the second bump 05, the total height of the first bump 04 and the adhesion material is equal to the height of the second bump 05, such that the piezoelectric element after adhesion is placed horizontally.

It should be noted that the moved element is arranged above the region surrounded by the second bump 05, so when the moved element, such as an aperture and a lens, needs to transmit light, the first dielectric layer 03 in the internal region surrounded by the second bump 05 needs to be etched, as shown in FIG. 3 and FIG. 4, there are two pairs of first bumps 04 surrounding the second bumps 05, and there are two pairs of second bumps 05 symmetrically distributed below the moved element. The internal region surrounded by each second bump 05 is hollow. In this embodiment, the second bump 05 is L-shaped, and in the later process, two sides of “L” may correspond to one piezoelectric element respectively, that is, four second bumps 05 correspond to eight piezoelectric elements. Of course, a shape of the second bump 05 is not limited to this, as long as the second bump 05 and the bottom surface of the piezoelectric element can form opposite parts and piezoelectric element can drive the moved element to move up and down.

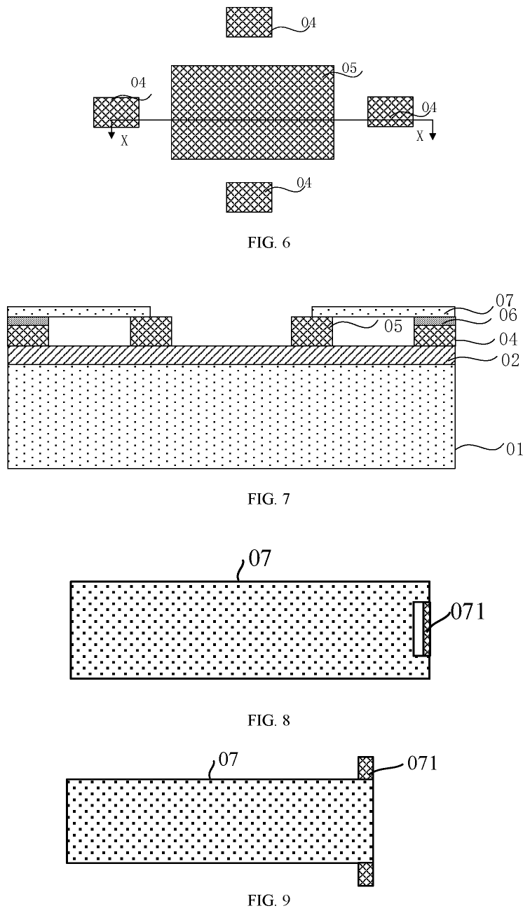

In another embodiment, when the moved element does not need to transmit light, the first dielectric layer 03 in the region surrounded by the second bump 05 may not be etched. Referring to FIG. 5 and FIG. 6, FIG. 6 is a top view, and FIG. 5 is a sectional view along an X-X direction in FIG. 6. There are two pairs of first bumps 04 symmetrically distributed on two sides of the moved element, and the second bump 05, as a whole body, is located below the moved element. It should be understood that FIG. 4 to FIG. 6 are only intended to describe two situations where the region surrounded by the second bump 05 is etched and is not etched. In this embodiment of the present disclosure, the first bump 04 and the second bump 05 may form various other distribution structures. For example, in one embodiment, the first bump 04 and the second bump 05 are located below the moved element which is placed subsequently.

There are one pair of first bumps 04 and one pair of second bumps 05. The first bumps 04 are located between the two second bumps 05, and the first bumps 04 and the second bumps 05 are all located below the moved element 09. In another embodiment, there are one pair of first bumps 04 and the second bumps 05, the first bumps 04 and the second bumps 05 are all located below the moved element, and the first bumps 04 are located between the two second bumps 05, that is, when the first bumps 04 and the second bumps 05 are all located below the moved element 09, the positions of the first bumps 04 and the second bumps 05 may be interchanged.

A piezoelectric element is provided, one end of the piezoelectric element adheres to the first bump through a first adhesion material and the other end of the piezoelectric element is at least partially located above the second bump.

Referring to FIG. 7, the piezoelectric element 07 is provided, one end of the piezoelectric element 07 adheres to the first bump 04 through the first adhesion material 06 and the other end of the piezoelectric element 07 is at least partially located above the second bump 05, and under a power-on state, the other end of the piezoelectric element 07 is warped upwards or downwards so as to drive the moved element to move upwards or downwards. The first adhesion material 06 includes a dry film or a structural adhesive. Specifically, in one embodiment, the first adhesion material 06 is the structural adhesive, the structural adhesive is formed on an upper surface of the first bump 04 in an adhesive dispensing mode, a thickness of the structural adhesive is a difference between the height of the first bump 04 and the second bump 05, one end of the piezoelectric element 07 adheres to the first bump 04, and the other end of the piezoelectric element 07 extends above the second bump 05. In this embodiment, the tail end of the piezoelectric element 07 is at a distance away from an edge of the first bump 05 along an extending direction of the piezoelectric element 07. In the later process, the first adhesion material is configured to adhere the moved element. In other examples, if the region to which the moved element is adhered is on a side of the piezoelectric element 07, this limitation is not required.

In another embodiment, the first adhesion material 06 is a dry film. A method for forming a first adhesion layer includes: a bottom surface of the piezoelectric element 07 is covered with an initial dry film of which a thickness is a difference between a height of the first bump 04 and a height of the second bump 05, part of the dry film is removed by a patterning process, the dry in the region corresponding to the first bump 04 is remained, and the piezoelectric element 07 adheres to the first bump 04 through the patterned dry film after position alignment.

Referring to FIG. 8 and FIG. 9, FIG. 8 is a structural schematic diagram of a piezoelectric element with a rotating shaft structure according to an embodiment of the present disclosure. FIG. 9 is a structural schematic diagram of another piezoelectric element with a rotating shaft structure according to an embodiment of the present disclosure. FIG. 8 and FIG. 9 are schematic diagrams of two piezoelectric elements 07 with rotating shaft 071 structures. A material of the rotating shaft 071 is a dielectric material. When one end of the piezoelectric element 07 adheres to the first bump 04, the rotating shaft 071 is located above the second bump 05. When the piezoelectric element 07 is warped, the rotating shaft 071 can rotate and slide in a groove so as to prevent one end, in contact with the moved element, of the piezoelectric element 07 from being stuck. A height of the formed groove is greater than and equal to a diameter of the rotating shaft 071, and a length of the groove is greater than a length of the rotating shaft 071. When the height of the groove is equal to the diameter of the rotating shaft 071, the lifting and lowering amount of the moved element 09 may be controlled well, and it is unnecessary to overcome a space allowance between the rotating shaft 071 and the groove.

In FIG. 8, the rotating shaft 071 is distributed at the center of an end part of a movable end of the piezoelectric element 07, and one or more rotating shafts may be distributed. There is a gap between the rotating shaft 071 and the piezoelectric element 07 in a direction vertical to an axial direction of the rotating shaft 071, such that the rotating shaft 071 is arranged above the second bump 05, and other parts of the piezoelectric element 07 are not located above the second bump 05 to prevent from being stuck. In FIG. 9, two rotating shafts 071 are located on two sides of the movable end of the piezoelectric element 07 respectively and extend out along a direction departing from the piezoelectric element 07, and each rotating shaft 071 s arranged above the second bump 05.

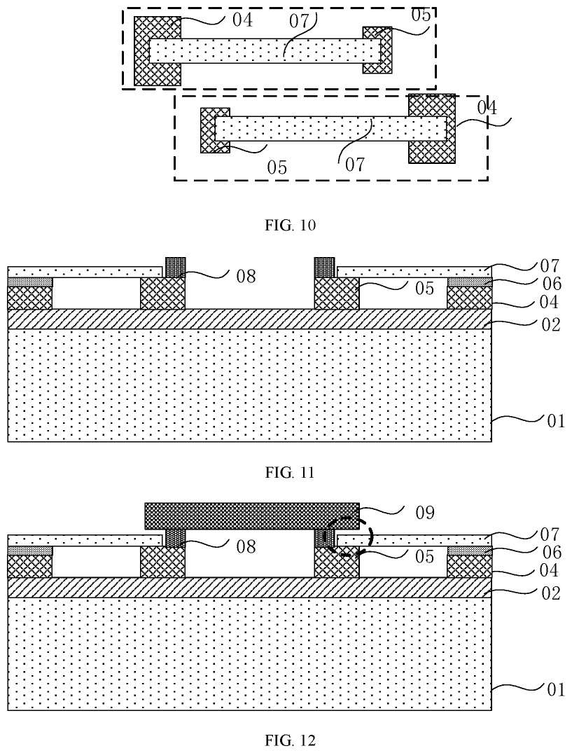

Referring to FIG. 10, in one embodiment, there are one pair of first bumps 04 and one pair of second bumps 05. The first bump 04 and the second bump 05 away from the first bump 04 form one group. As shown in a dashed box in the figure, there are upper and lower groups. During adhesion of the piezoelectric element 07, one end of the piezoelectric element 07 is fixed on one of the first bumps 05 and the other end of the piezoelectric element 07 extends onto the second bump 04 at a further distance, so that the two piezoelectric elements 07 are arranged below the moved element 09 in an overlapping manner, that is, each piezoelectric element 07 is configured to move an opposite side of the moved element 09. At this time, a length of the piezoelectric element 07 may be increased. When the mass of the moved element 09 is large, the piezoelectric element 07 may be easily lifted.

Referring to FIG. 11 to FIG. 16, the moved element 09 adheres to the second bump 05 through a second adhesion material 08, the moved element 09 and the second bump 05 have opposite parts, a groove is surrounded by the moved element 09, the second adhesion material 08 and the second bump 05, or the moved element 09 is provided with a film layer 10 extending out of the moved element 09, and a grove is surrounded by the film layer 10, the second adhesion material 08 and the second bump 05.

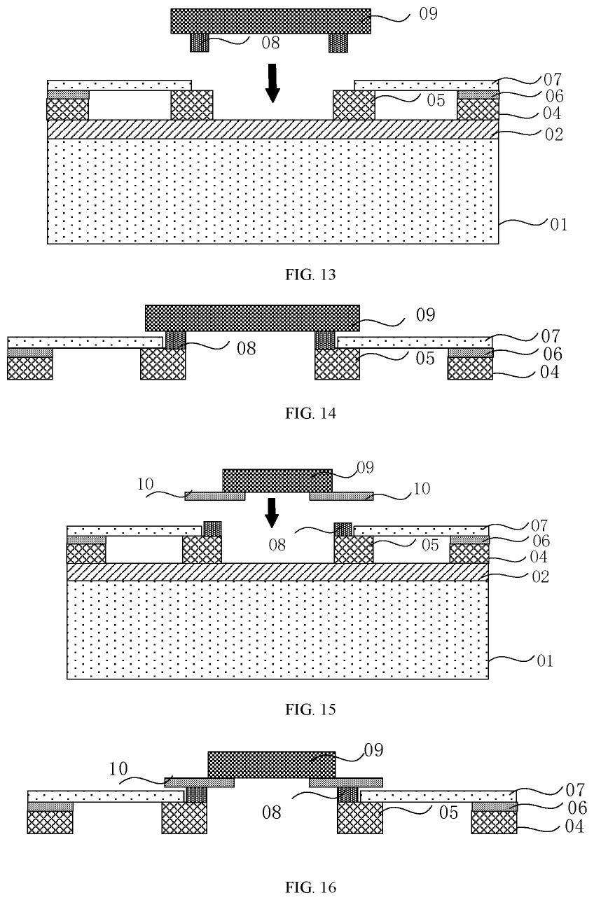

Specifically, in one embodiment, referring to FIG. 11 and FIG. 12, the second adhesion material 08 is a structural adhesive, and a region not covered with the piezoelectric element 07 is coated with the structural adhesive. In this embodiment, a position coated with the structural adhesive is located between a tail end of a movable end of the piezoelectric element 07 and an edge of the second bump 05, a thickness of the structural adhesive is greater than a thickness of the piezoelectric element 07, the moved element 09 adheres to the second bump 05, the moved element 09 and the second bump 05 have opposite parts, and a groove (as shown in an elliptical dotted line) is surrounded by the moved element 09, the second adhesion material 08 and the second bump 05. In another embodiment, referring to FIG. 13, the second adhesion material 08 is a dry film, a bottom surface of the moved element 09 is covered with the dry film, a thickness of the dry film is greater than a thickness of the piezoelectric element 07, part of the dry film is removed by a patterning process, the dry film in a region adhered to the second bump 05 is remained, the moved element 09 adheres to the second bump 05 after position alignment, the moved element 09 and the second bump 05 have opposite parts, and a groove is surrounded by the moved element 09, the second adhesion material 08 and the second bump 05.

Referring to FIG. 14, debonding is performed to remove the first substrate 01. Specifically, when the bonding film 02 is a pyrolysis film, the pyrolysis film loses viscosity by high temperature, and a structure formed thereon is sucked by a suction nozzle. When the bonding film 02 is an ultraviolet photolysis film, the ultraviolet light is irradiated from a bottom surface of the first substrate 01, such that the ultraviolet photolysis film loses viscosity. When the bonding film 02 is the ultraviolet photolysis film, an electrostatic film (not shown in the figure) below the first substrate 01 should be removed first. In another embodiment, referring to FIG. 15, there are one pair of second bumps 05, a size of the moved element 09 is small, a lower surface of the moved element 09 cannot form opposite parts with two second bumps 05, and a film layer 10 is added below a surface of the moved element 09. The film layer 10 extends out of the lower surface of the moved element 09, such that the film layer 10 forms an opposite part with the second bump 05. Specifically, before the moved element 09 adheres to the second bump 05, one film layer 10 adheres to the lower surface of the moved element 09. When the moved element 09 does not need to transmit light, the film layer 10 may completely cover the lower surface of the moved element 09. When the moved element 09 needs to transmit light, a film layer 10 is formed on the edge of the moved element 09. A groove formed by the film layer 10, the second bump 5 and the second adhesion material 08 is located on an outer side below the moved element 09. A material of the film layer 10 is not limited and may be a semiconductor material or an insulating material, such as silicon, germanium, silicon dioxide and silicon nitride. In this embodiment, the film layer 10 is monocrystalline silicon and adheres to the edge of the bottom surface of the moved element 09 after being thinned.

Referring to FIG. 16, debonding is performed to remove the first substrate. The debonding method refers to the aforementioned embodiments, which will not be elaborated herein. FIG. 16 is a structural schematic diagram of an imaging module formed after the first substrate is removed.

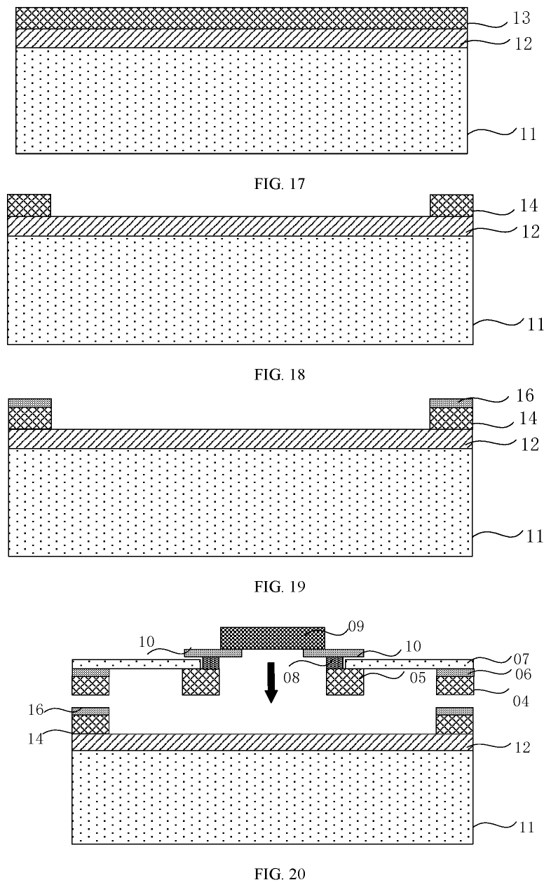

In the imaging module provided by the above embodiment, the piezoelectric element only can lift the moved element 09 upwards, but cannot move the moved element 09 downwards. The method for manufacturing the imaging module provided by the present disclosure further provides another embodiment, referring to FIG. 17 to FIG. 21. The difference between this embodiment and the aforementioned embodiments is that after the first substrate is removed, the method further includes: a third bump is adhered to a part below the first bump, such that the second bump is in a suspended state. By this arrangement mode, the moved element can move up and down.

A second substrate 11 is provided, and a second dielectric layer 12 is bonded on the second substrate 11; the second dielectric layer 12 is patterned to form a third bump 14, wherein the third bump 14 and the first bump 04 have the same structure and distribution; and the third bump 14 is adhered to a part below the first bump 04, or the second substrate 11 is removed after the first bump 04 adheres to the third bump 14. Specifically, referring to FIG. 17 to FIG. 19, a material of the second substrate 11 refers to the material of the first substrate 01, and a material of the second dielectric layer 12 refers to the material of the first dielectric layer 02. A method for bonding the second dielectric layer 12 on the second substrate 11 refers to the method for bonding the first dielectric layer 02 on the first substrate 01, the second dielectric layer 12 is patterned to form the third bump 14, and the process details refer to the above, which is not elaborated herein. The third bump 14 has the same structure and distribution as those of the first bump 04, which means that the third bump 14 is configured to bearing the first bump 04, the third bump 14 is arranged below the first bump 04 after the first bump 04 adheres to the third bumps, and in an optional solution, the first bump 04 and the third bump 14 have the same shape and size. It should be understood that the third bump 14 is configured to bear the first bump 04, and the structure of the third bump 14 is not strictly limited on the premise of ensuring the bearing function of the third bump 14.

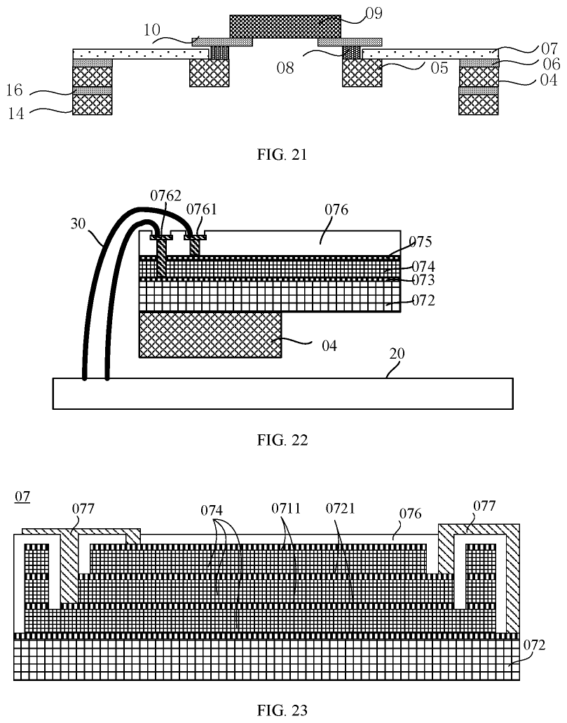

Referring to FIG. 20, after the third bump 14 is formed, the third bump 14 adheres to a bottom surface of the first bump 04 through a third adhesion material 16, the third adhesion material 16 includes a structural adhesive or a dry film, and the adhesion method refers to the adhesion method of the first adhesion material 06 and the second adhesion material 08 described above. In this example, the third adhesion material 16 is formed on an upper surface of the third bump 14. In other examples, the third adhesion material 16 may also be formed on the lower surface of the first bump 04, or the second substrate 11 is removed and then the third bump 14 adheres to the lower surface of the first bump 04.

Referring to FIG. 21, the third bump 14 is adhered to a part below the first bump 04, or the second substrate 11 is removed after the first bump 04 adheres to the third bump 14.

In the above embodiment, the piezoelectric element 07 needs to introduce a charge material for deformation. In one embodiment, referring to FIG. 22, the piezoelectric element 07 includes a supporting layer 072 and a piezoelectric laminated structure located on the supporting layer 072. The piezoelectric laminated structure includes a second electrode 073, a piezoelectric film 074 and a first electrode 075 which are stacked sequentially from bottom to top, wherein an insulating layer 076 is arranged above the first electrode 075, the first electrode 075 and the second electrode 073 are connected to a first electrode leading-out end 0761 and a second electrode leading-out end 0762 respectively, and the first electrode leading-out end 0761 and the second electrode leading-out end 0762 are both located in the insulating layer 076.

In the present disclosure, the first electrode leading-out end 0761 and the second electrode leading-out end 0762 may be both located on a bottom surface of the piezoelectric 07, that is, the first electrode leading-out end 0761 and the second electrode leading-out end 0762 are located in the supporting layer 072, or the first electrode leading-out end 0761 and the second electrode leading-out end 0762 are located on a top surface and the bottom surface of the piezoelectric element 07 respectively, which is not limited by the present disclosure.

Continuously referring to FIG. 22, the first electrode leading-out end 0761 and the second electrode leading-out end 0762 are located on the top surface of the piezoelectric element 07, and the piezoelectric element 07 is located on the top surface of the first bump 04. The first electrode leading-out end 0761 and the second electrode leading-out end 0762 directly serve as external signal connection ends and are electrically connected to a circuit board 20 respectively through one lead 30, such that the circuit board 20 may apply a voltage to the piezoelectric element 07, and a voltage difference is generated between an upper surface and a lower surface of a piezoelectric film 074, thereby shrinking the piezoelectric film 074. However, since the supporting layer 072 cannot extend and retract, the piezoelectric element 07 is warped upwards or downwards (the warping direction and the warping degree depend on the voltage applied to the upper and lower surfaces of the piezoelectric film 074) after being powered on, such that the piezoelectric element 07 is entirely bent upwards or downwards and the moved element 09 may entirely move upwards or downwards, thereby changing a vertical position of the moved element 09 and realizing optical automatic focusing. After automatic focusing is completed, when necessary, the voltage applied to the piezoelectric element 07 on one side of the moved element 09 may be changed, such that the moved element 09 inclines, thereby changing the angle of the moved element 09, correcting an optical warping angle of the moved element 09 and preventing optical jittering.

In addition, in other embodiments, the piezoelectric laminated structure of the piezoelectric element 07 may not be limited only one layer of piezoelectric film 074. Referring to FIG. 23, the piezoelectric laminated structure of the piezoelectric element 07 may be a piezoelectric laminated structure with three layers of piezoelectric films 074, electrodes are distributed on an upper surface and an lower surface of each layer of piezoelectric film 074, and the adjacent two layers of piezoelectric films 074 share the electrode located therebetween, so there are totally four layers of electrodes on the three layers of piezoelectric films 074, the electrodes are counted sequentially from bottom to top, the odd-layer electrodes 0711 are electrically connected together through a conductive structure 077, the even-layer electrodes 0721 are electrically connected together through another conductive structure 077, a part, extending into the piezoelectric laminated structure, of the conductive structure 077 needs to be located in the insulating layer 076, and only the end part of the conductive structure 077 is in contact with the electrodes requiring electrical connection. Tops of the two conductive structures 077 may serve as the first electrode leading-out end 0761 and the second electrode leading-out end 0762 respectively, such that the first electrode leading-out end 0761 and the second electrode leading-out end 0762 are both located on a top surface of the piezoelectric element 07.

In the present disclosure, the piezoelectric laminated structure is not limited to including three layers of piezoelectric films and may also include three layers, four layers, five layers or six layers, etc. The warping ability of the piezoelectric element 07 may be improved by increasing the number of the piezoelectric films 074, such that the piezoelectric element 07 can move the moved element 09 with larger mass. Further, the electrical connection mode of the odd-layer electrodes 0711 and the even-layer electrodes 0721 are not limited to the conductive structure 077 shown in FIG. 25, and the electrical connection mode of the odd-layer electrodes 0711 and the even-layer electrodes 0721 may also be electrically connected through a conductive plug and an interconnecting line. The two conductive structures 077 may lead the odd-layer electrodes 0711 and the even-layer electrodes 0721 to the bottom surface of the supporting layer 072, such that the first electrode leading-out end 0761 and the second electrode leading-out end 0762 are both located on the bottom surface of the piezoelectric element 07, or the two conductive structures 077 may also lead the odd-layer electrodes 0711 and the even-layer electrodes 0721 to the top surface of the piezoelectric element 07 and the bottom surface of the supporting layer 072 respectively, such that the first electrode leading-out end 0761 and the second electrode leading-out end 0762 are both located on the top surface and the bottom surface of the piezoelectric element 07, which are thus not illustrated one by one. It should be understood that in order to ensure the same warping direction of the three layers of piezoelectric films, the polarities of the adjacent two layers of piezoelectric films are opposite.

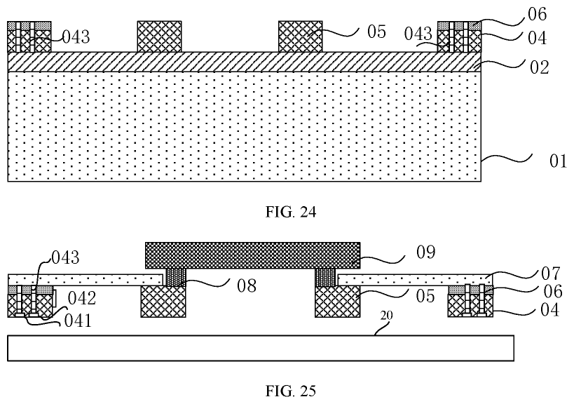

Referring to FIG. 24, in yet another embodiment, after the first bump 04 is formed and before adhesion of the piezoelectric element 07, an interconnection structure, such as a conductive plug 043, penetrating through the first bump 04 and the first adhesion material 06 is formed in the first bump 04. During adhesion of the piezoelectric element, the first electrode leading-out end and the second electrode leading-out end correspond to one conductive plug 043. After the first substrate 01 is removed, a first electrical connection end and a second electrical connection end are formed on the bottom surface of the first bump 04 and are electrically connected to one conductive plug 043 respectively to serve as external signal connection ends, and the external signal connection ends are electrically connected to an external circuit, for example, electrically connected to a circuit board.

Referring to FIG. 25, in another embodiment, after the first substrate 01 is removed, an interconnection structure, such as a conductive plug 043, penetrating through the first bump 04 and the first adhesion material 06 is formed in the first bump 04 and is electrically connected to the first electrode leading-out end and the second electrode leading-out end respectively. A first electrical connection end 041 and a second electrical connection end 042 are formed on the bottom surface of the first bump 04 and are electrically connected to one conductive plug 043 respectively to serve as external signal connection ends, electrically connected to a circuit board 20.

It should be noted that each embodiment in the specification is described by a relevant mode, the same or similar part between each embodiment may refer to each other, and each embodiment focuses on the difference from other embodiments. In particular, for the structural embodiment which is basically similar to the method embodiment, the description is relatively simple, and the relevant points are referenced to the partial description of the method embodiment.

The above description is only the description of the preferred embodiment of the present disclosure and does not constitute any limitation to the scope of the present disclosure. Any changes and modifications made by those of ordinary skill in the field of the present disclosure according to the content disclosed above shall fall within the protection scope of the claims.

1. A method for manufacturing an imaging module, the imaging module comprising a moved element, the moved element comprising: an imaging sensing element, an aperture, a lens or a reflector, and the method comprising:
providing a first substrate and bonding a first dielectric layer on the first substrate;
patterning the first dielectric layer to form at least one first bump and at least one second bump, wherein the at least one first bump and the at least one second bump are mutually independent, and a region surrounded by the at least one second bump defines a location region of the moved element;
providing a piezoelectric element, adhering one end of the piezoelectric element to the first bump through a first adhesion material and making the other end of the piezoelectric element at least partially located above the second bump, wherein under the power-on state, the other end of the piezoelectric element is warped upwards or downwards so as to drive the moved element to move upwards or downwards;
adhering the moved element to the second bump through a second adhesion material, wherein the moved element and the second bump have opposite parts, a groove is surrounded by the moved element, the second adhesion material and the second bump, or the moved element is provided with a film layer extending out of the moved element and a groove is surrounded by the film layer, the second adhesion material and the second bump; and
debonding to remove the first substrate.

2. The method for manufacturing the imaging module according to claim 1, wherein when one end of the piezoelectric element adheres to the first bump, an end part of the other end of the piezoelectric element is located above the second bump.

3. The method for manufacturing the imaging module according to claim 1, wherein the piezoelectric element comprises a rotating shaft arranged on or between two sides of the other end, the rotating shaft being located above the second bump when one end of the piezoelectric element adheres to the first bump.

4. The method for manufacturing the imaging module according to claim 1, wherein the first bump is annular or there is at least one pair of first bumps surrounding the second bumps, and the second bumps are symmetrically distributed at the periphery or below the moved element.

5. The method for manufacturing the imaging module according to claim 1, wherein there is at least one pair of first bumps symmetrically distributed below the moved element, and the second bump is located at the periphery of the first bumps and corresponds to the first bumps; and wherein there is at least one pair of piezoelectric elements, and the two paired piezoelectric elements are distributed on two sides of the center of the moved element; or the two paired piezoelectric elements are arranged in an overlapping manner.

6. (canceled)

7. The method for manufacturing the imaging module according to claim 1, wherein when the first substrate is an opaque material, the first dielectric layer is bonded on the first substrate by a pyrolysis film; and when the first substrate is a translucent material, the first dielectric layer is bonded on the first substrate by an ultraviolet photolysis film or a pyrolysis film; and before the debonding, the method further comprising: removing the electrostatic film.

8. The method for manufacturing the imaging module according to claim 7, when the first dielectric layer is bonded by the ultraviolet photolysis film, before the step of patterning the first dielectric layer, the method further comprising: adhering an electrostatic film to one side, departing from the first dielectric layer, of the first substrate, the electrostatic film having conductivity and being not completely translucent.

9. The method for manufacturing the imaging module according to claim 7, wherein the debonding method comprises: when the bonding film is the pyrolysis film, heating the pyrolysis film to deactivate the pyrolysis film; and when the bonding film is the ultraviolet photolysis film, irradiating a bottom surface of the first substrate by ultraviolet light to deactivate the ultraviolet photolysis film.

10. (canceled)

11. The method for manufacturing the imaging module according to claim 1, wherein the step of patterning the first dielectric layer, comprises: coating the first dielectric layer with a photosensitive material, performing exposure development by masks with different light transmittance patterns, and etching the first dielectric layer, such that a height of the first bump is less than that of the second bump.

12. The method for manufacturing the imaging module according to claim 11, wherein when the first adhesion material is formed, a height of the first adhesion material is equal to a difference between the height of the first bump and the height of the second bump, such that a top surface of the piezoelectric element is parallel to a top surface of the first substrate.

13. The method for manufacturing the imaging module according to claim 1, wherein the first adhesion material and the second adhesion material comprise a dry film or a structural adhesive.

14. The method for manufacturing the imaging module according to claim 1, wherein the step of adhering the moved element to the second bump by the second adhesion material, comprises:
forming a second adhesion material layer on a bottom surface of the piezoelectric element or a bottom surface of the film layer, patterning the second adhesion material, retaining a second adhesion material corresponding to a to-be-adhered region of the second bump, and adhering the moved element to the second bump after location alignment.

15. The method for manufacturing the imaging module according to claim 1, wherein a method for forming the film layer on the moved element comprises: adhering the film layer which is manufactured in advance to the moved element and making the film layer and the second bump be provided with opposite parts.

16. The method for manufacturing the imaging module according to claim 1, after the step of removing the first substrate, the method further comprising:
providing a second substrate and bonding a second dielectric layer on the second substrate;
patterning the second dielectric layer to form a third bump, wherein the third bump and the first bump have the same structure and distribution; and
removing the second substrate and adhering the third bump to a part below the first bump, or removing the second substrate after adhering the first bump to the third bump.

17. The method for manufacturing the imaging module according to claim 1, wherein the piezoelectric element comprises:
a piezoelectric laminated structure, at least comprising one layer of piezoelectric film, and electrodes located on upper and lower surfaces of each layer of the piezoelectric film, the adjacent two layers of the piezoelectric films sharing the electrode located therebetween, and
the electrodes being counted sequentially from bottom to top and being divided into odd-layer electrodes and even-layer electrodes;
a first electrode leading-out end, located on a top or bottom surface of the piezoelectric element and electrically connected to the even electrode layer; and
a second electrode leading-out end, located on the top surface or bottom surface of the piezoelectric element and electrically connected to the odd electrode layer.

18. The method for manufacturing the imaging module according to claim 17, the method further comprising: forming an external signal connection end which is electrically connected to the first electrode leading-out end and the second electrode leading-out end.

19. The method for manufacturing the imaging module according to claim 18, wherein
the first electrode leading-out end and the second electrode leading-out end are located on the top surface of the piezoelectric element, and the first electrode leading-out end and the second electrode leading-out end serve as the external signal connection ends.

20. The method for manufacturing the imaging module according to claim 18, wherein the first electrode leading-out end and the second electrode leading-out end are located on the bottom surface of the piezoelectric element, and the method further comprises:
before adhering the piezoelectric element to the first bump, forming an interconnection structure penetrating through the first bump in the first bump;
after removing the first substrate, forming a first electrical connection end and a second electrical connection end on a bottom surface of the first bump; and
electrically connecting the first electrode leading-out end and the second electrode leading-out end with the first electrical connection end and the second electrical connection end respectively through one interconnection structure.

21. The method for manufacturing the imaging module according to claim 18, wherein the first electrode leading-out end and the second electrode leading-out end are located on the bottom surface of the piezoelectric element, and the method comprises:
after removing the first substrate, forming an interconnection structure penetrating through the first bump in the first bump and forming a first electrical connection end and a second electrical connection end on a bottom surface of the first bump; and
electrically connecting the first electrode leading-out end and the second electrode leading-out end with the first electrical connection end and the second electrical connection end respectively through one interconnection structure.

22. The method for manufacturing the imaging module according to claim 16, wherein materials of the first dielectric layer, the second dielectric layer and the film layer comprise any one of silicon, germanium, germanium silicon, silicon carbide, germanium-silicon carbide, indium arsenide or gallium arsenide.
